(19) United States
(12) Patent Application Publication
(10) Pub. No.: US 2026/0047114 A1
(43) Pub. Date: Feb. 12, 2026

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventor: HSIU-YING CHO, HSIN CHU CITY (TW)

(21) Appl. No.: 18/797,554

(22) Filed: Aug. 8, 2024

(51) Int. Cl. H01L 23/522

(52) U.S. Cl. CPC H10D 1/716; H01L 23/5223; H01L 23/5225; H10D 1/20; H10D 1/714

(57) ABSTRACT

A semiconductor device and a method of manufacturing the semiconductor device are provided. The semiconductor device includes a substrate, a capacitor component, an inductor component, and an interconnect structure. The capacitor component is disposed over the substrate and includes an anode assembly and a cathode assembly electrically insulated from the anode assembly. The inductor component is disposed on and vertically aligned with the capacitor component, wherein the inductor component includes a signal line and a shielding assembly between the signal line and the capacitor component. The interconnect structure is disposed over the substrate and surrounds the capacitor component and the inductor component.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of integrated circuit evolution, functional density (i.e., the number of interconnected devices per chip area) has generally increased while geometry size (i.e., the size of the smallest component (or line) that can be created using a fabrication process) has decreased.

Various active or passive electronic components can be formed on a semiconductor IC. For example, transformers, inductors, capacitors, etc., may be formed on a semiconductor IC. However, conventional electronic components formed on an IC may incur shortcomings such as excess space consumption, poor device performance, inadequate shielding, and high fabrication costs.

Therefore, while existing electronic components on semiconductor ICs have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic cross-sectional view of a semiconductor device, in accordance with some embodiments of the present disclosure.

FIG. 2 is a schematic circuit diagram of an integrated circuit, in accordance with some embodiments of the present disclosure.

FIG. 3 is a schematic perspective view of a stacked structure that includes a capacitor component and an inductor component of the semiconductor device, in accordance with some embodiments of the present disclosure.

FIG. 4 is a schematic perspective view of a capacitor component, in accordance with some embodiments of the present disclosure.

FIG. 5 is a schematic cross-sectional view along a line A-A′ of the capacitor component in FIG. 4.

FIG. 6 is a schematic perspective view of an inductor component, in accordance with some embodiments of the present disclosure.

FIG. 7 is a schematic perspective view of a capacitor component, in accordance with some embodiments of the present disclosure.

FIG. 8 is a schematic perspective view of a portion of a capacitor component illustrating some embodiments of the present disclosure that include a plurality of first anode members, a plurality of first cathode members, a plurality of third anode members, and a third cathode member.

FIG. 9 is a schematic perspective view of a capacitor component, in accordance with some embodiments of the present disclosure.

FIG. 10 is a cross-sectional view along a line B-B′ of the capacitor component in FIG. 9.

FIG. 11 is a schematic perspective view of an inductor component, in accordance with some embodiments of the present disclosure.

FIG. 12 is a schematic perspective view of an inductor component, in accordance with some embodiments of the present disclosure.

FIG. 13 is a schematic perspective view of an inductor component, in accordance with some embodiments of the present disclosure.

FIG. 14 is a schematic cross-sectional view of a semiconductor device, in accordance with some embodiments of the present disclosure.

FIG. 15 is a schematic cross-sectional view of a semiconductor device, in accordance with some embodiments of the present disclosure.

FIG. 16 is a schematic cross-sectional view of a semiconductor device, in accordance with some embodiments of the present disclosure.

FIG. 17 is a flowchart of a method of manufacturing a semiconductor device, in accordance with some embodiments of the present disclosure.

FIGS. 18 to 20 are cross-sectional views of intermediate stages of the method of manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for a purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure provides a semiconductor device including stacked capacitor components and inductor components embedded in an interconnect structure. The inductor components include a shielding assembly around a signal line. Since the signal line is shielded by the shielding assembly, the capacitor component is able to be positioned over or under the inductor component. One advantage offered by the semiconductor device is the reduced footprint.

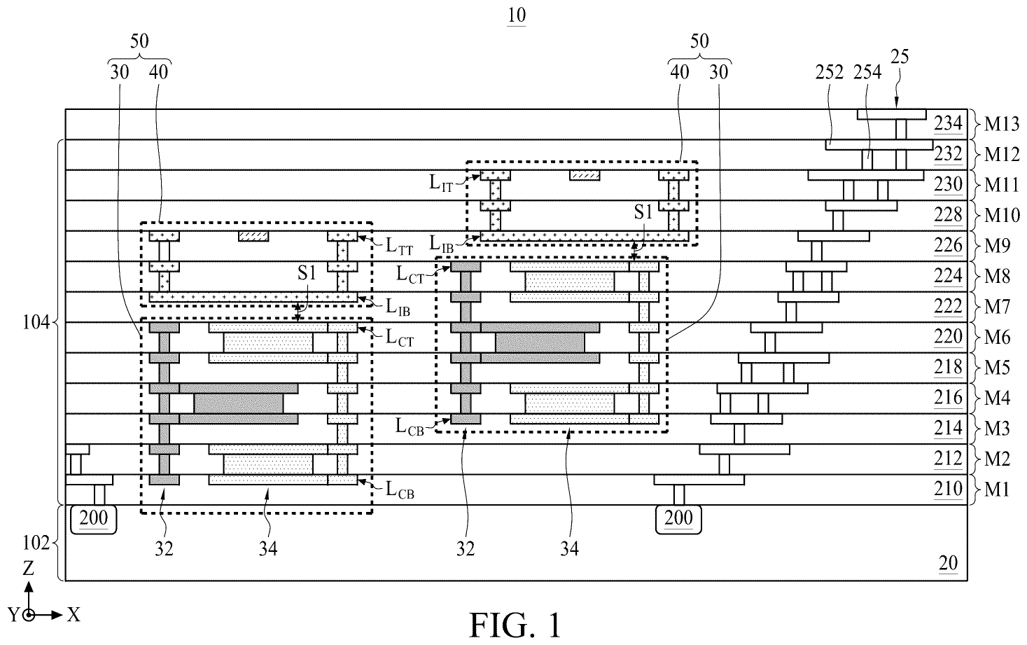

FIG. 1 is a cross-sectional view of a semiconductor device 10, in accordance with some embodiments of the present disclosure. Referring to FIG. 1, in some embodiments, the semiconductor device 10 includes a device layer 102 and an interconnect layer 104 disposed over the device layer 102. The device layer 102 includes a substrate 20 and one or more semiconductor components 200 (e.g., transistors, resistors, or the like) disposed in and/or on the substrate 20. The interconnect layer 104 includes an interconnect structure 25 and a plurality of passive components (e.g., capacitor components 30 and inductors 40) surrounded by the interconnect structure 25. The interconnect structure 25, the capacitor components 30, and the inductor components 40 are disposed over the substrate 20 and the semiconductor components 200. The substrate 20 may be a semiconductor substrate, and may include semiconductor materials such as silicon, germanium, and the like. The semiconductor components 200 may be formed in and/or on the substrate 20 in a front-end-of-line (FEOL) stage.

Electrical signals, such as power and/or input/output signals, may be routed to and/or from the semiconductor components 200, the capacitor components 30, and the inductor components 40 through the interconnect structure 25. The interconnect layer 104 includes a plurality of tiers (e.g., tiers M1 to M13), with each of the tiers M1 to M13 including conductive features and at least one insulating layer (e.g., the insulating layer 210, 212, 214, 216, 218, 220, 222, 224, 226, 228, 230, 232, or 234). Although FIG. 1 shows merely thirteen tiers, the scope of this application is not limited thereto. In some embodiments, the interconnect layer 104 can include more or fewer than thirteen tiers.

In some embodiments, the conductive features include alternating conductive lines 252 and conductive vias 254. In some embodiments, the conductive lines 252 extend horizontally in the tiers M1 to M13, and the conductive vias 254 extend vertically to provide electrical connections between the conductive lines 252 in different tiers. For example, a conductive via 254 allows a conductive line 252 from the tier M1 to be electrically connected to another conductive line 252 from the tier M2.

The conductive lines 252 and the conductive vias 254 of the interconnect structure 25, the capacitor components 30, and the inductor components 40 may be formed in the insulating layers 210 to 234. The insulating layers 210 to 234 may each include an oxide (such as silicon oxide), a nitride (such as silicon nitride), an oxynitride (such as silicon oxynitride), a carbide (such as silicon carbide), an oxycarbide (such as silicon oxycarbide), a low-dielectric-constant (low-k) dielectric material, an ultra-low-k dielectric material, other dielectric materials, or a combination thereof. The interconnect structure 25, the capacitor components 30, and the inductor components 40 may be formed in or on the substrate 20 in a back-end-of-line (BEOL) stage.

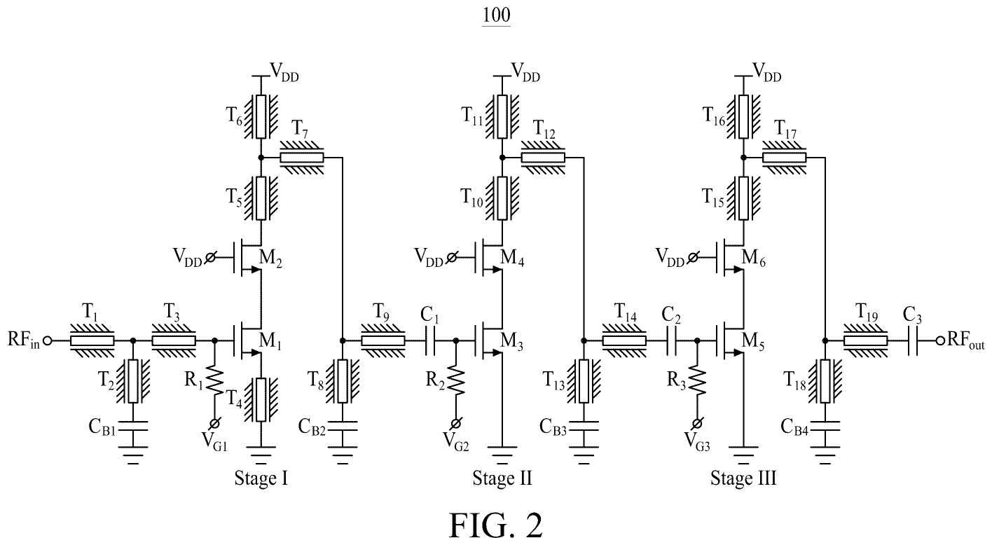

Although FIG. 1 shows merely two capacitor components 30 constructed in a same configuration and two inductor components 40 constructed in a same configurations, the scope of this application is not limited thereto. In some embodiments, more than two capacitor components constructed in the same or different configurations and more than two inductor components constructed in the same of different configurations can be included in the semiconductor device 10. The interconnect structure 25 may connects the semiconductor components 200 formed in the substrate 20, the multiple capacitor components, and the multiple inductor components to form an integrated circuit including a low-noise amplifier (LNA) 100, as shown in FIG. 2.

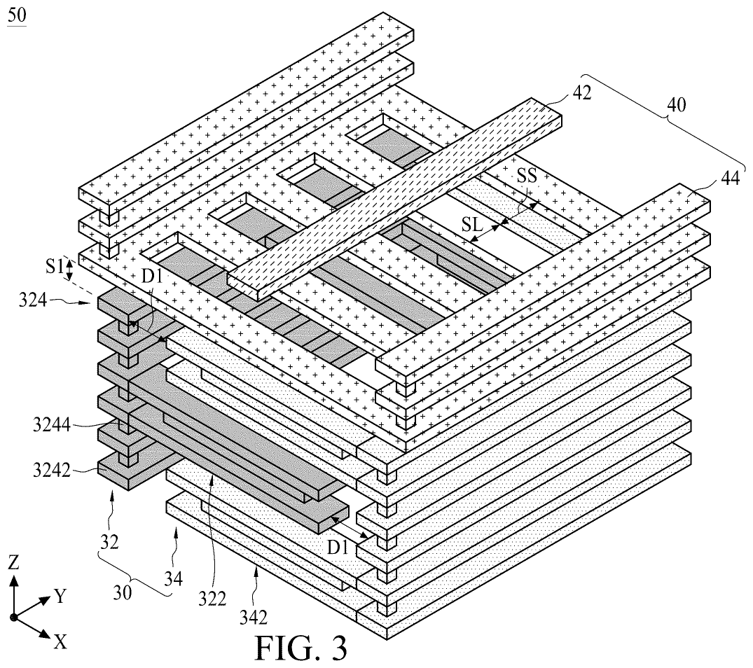

Referring again to FIG. 1, in some embodiments, the capacitor components 30 and the inductor components 40 are embedded in the interconnect structure 25. The capacitor components 30 and the inductor components 40 may be formed simultaneously with the interconnect structure 25. In some embodiments, the capacitor component 30 and the inductor component 40 are stacked on top of one another, to thereby reduce a footprint of the capacitor components 30 and the inductor components 40 in the semiconductor device 10. For example, the inductor components 40 may be each stacked on one of the capacitor components 30 with an interval S1 in the Z-direction. The capacitor component 30 and the inductor component 40 stacked thereon are in combination referred to as a stacked structure 50, wherein a schematic perspective view of the stacked structure 50 is shown in FIG. 3. Referring to FIGS. 1 and 3, in some embodiments, the insulator component 40 partially overlaps the capacitor component 30 from a top-view perspective. In alternative embodiments, the insulator component 40 is vertically aligned with the capacitor component 30.

As shown in FIG. 1, the capacitor components 30 may each include a topmost layer L_{CT} and a bottommost layer L_{CB}, and the inductor components 40 may each include a topmost layer L_{IT} and a bottommost layer L_{IB}. The topmost layer L_{CT}/L_{IT} refers to the layer farthest from the substrate 20, and the bottommost layer L_{CB}/L_{IB} refers to the layer closest to the substrate 20. In the stacked structure 50, a top surface of the topmost layer L_{CT} of the capacitor component 30 may be separated from a bottom surface of the bottommost layer L_{IB} of inductor component 40 by an interval S1. In some embodiments, one or more insulating layers, such as the insulator layers 220/224, fill the interval S1 between the capacitor component 30 and the inductor component 40. The bottommost layer L_{CB} of each capacitor component 30 may be disposed in any tier of the interconnect layer 104 as long as the topmost layer L_{IT} is not a topmost layer of the interconnect layer 104. For example, in FIG. 1, the bottommost layers L_{CB} of the capacitor components 30 are placed in tiers M1 and M3 of the interconnect layer 104, respectively.

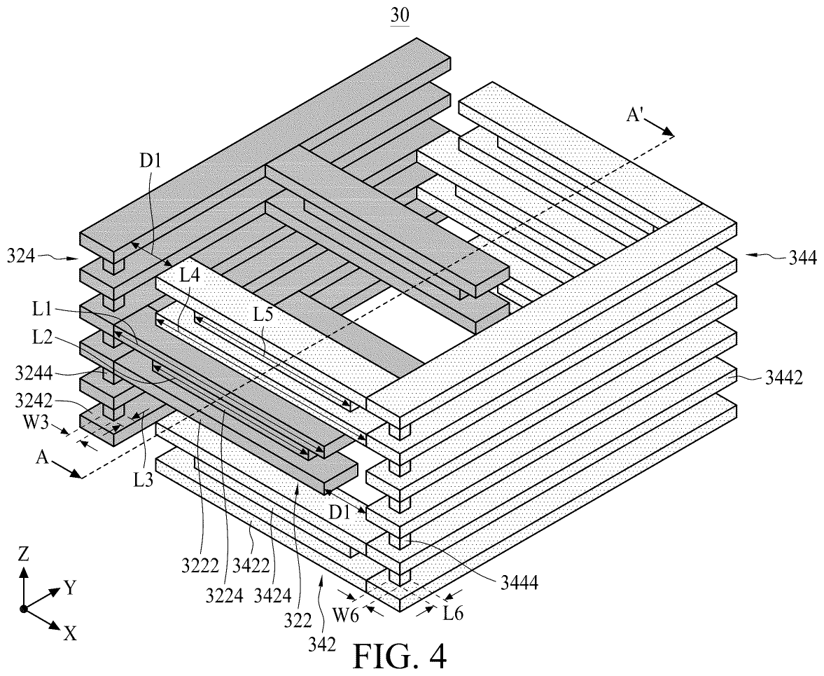

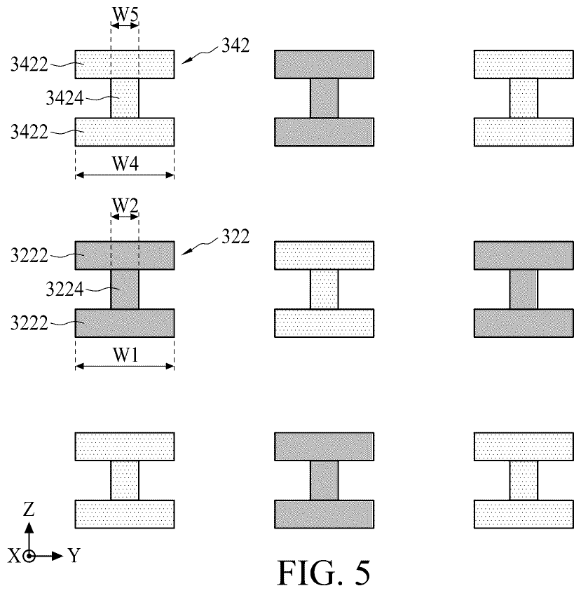

FIG. 4 is a schematic perspective view of the capacitor component 30, in accordance with some embodiments of the present disclosure, and FIG. 5 is a cross-sectional view along a line A-A′ of the capacitor component 30 in FIG. 4. Referring to FIGS. 3 and 4, the capacitor component 30 may have a cube-like shape. In some embodiments, the capacitor component 30 includes an anode assembly 32 and a cathode assembly 34 separated from and electrically insulated from the anode assembly 32. The anode and cathode assemblies 32 and 34 may not be in direct contact. The anode assembly 32 may function as an anode electrode of the capacitor component 30, and the cathode assembly 34 may function as a cathode electrode of the capacitor component 30. When voltages are applied to the anode electrode and the cathode electrode to cause a voltage difference, an electric field is generated between the anode assembly 32 and the cathode assembly 34. The voltages may be applied to the anode assembly 32 and the cathode assembly 34, e.g., by a power source, through the interconnect structure 25.

The anode assembly 32 may include a plurality of first anode members 322 and a second anode member 324. Each of the first anode members 322 includes a pair of first anode conductive lines 3222 and a first anode conductive via 3224. In some embodiments, the first anode conductive lines 3222 extend along the X-direction and are spaced apart from one another in the Z-direction substantially orthogonal to the X-direction. The first anode conductive via 3224 may extend along the X-direction and connect one of the first anode conductive lines 3222 to another of the first anode conductive lines 3222. In some embodiments, the first anode conductive via 3224 provides electrical connection between the first anode conductive lines 3222 in different tiers of the interconnect layer 104 shown in FIG. 1.

The first anode conductive lines 3222 have a length L1 defined along the X-direction and a width W1 defined in the Y-direction substantially orthogonal to the X-direction, wherein the length L1 may be substantially greater than the width W1. The first anode conductive via 3224 has a length L2 defined along the X-direction and a width W2 defined along the Y-direction, wherein the length L2 may be substantially greater than the width W2. The length L1 of the first anode conductive lines 3222 is greater than the length L2 of the first anode conductive via 3224. In some embodiments, the length L2 of the first anode conductive via 3224 is greater than half the length L1 of the first anode conductive lines 3222. The width W1 of the first anode conductive lines 3222 may be substantially greater than the width W2 of the first anode conductive via 3224. In some embodiments, the pair of first anode conductive lines 3222 and the first anode conductive via 3224 collectively form the first anode member 322 having an I-shaped cross-section.

In some embodiments, the second anode member 324 includes a plurality of second anode conductive lines 3242 and a plurality of second anode conductive vias 3244. The second anode conductive lines 3242 are substantially equally spaced and extend along the Y-direction. The second anode conductive lines 3242 are vertically spaced apart from each other in the Z-direction. Each of the second anode conductive vias 3244 connects two neighboring second anode conductive lines 3242 in different tiers of the interconnect layer 104 shown in FIG. 1. The second anode conductive vias 3244 have a length L3 in the Y-direction and a width W3 in the X-direction, wherein the length L3 may be substantially equal to the width W3.

The cathode assembly 34 may include a plurality of first cathode members 342 and a second cathode member 344. Each of the first cathode members 342 includes a pair of first cathode conductive lines 3422 and a first cathode conductive via 3424. In some embodiments, the first cathode conductive lines 3422 extend along the X-direction and are spaced apart from one another in the Z-direction. The first cathode conductive via 3424 may extend along the X-direction and connect one of the first cathode conductive lines 3422 to another of the first cathode conductive lines 3422. The first cathode conductive lines 3422 have a length L4 defined along the X-direction and a width W4 defined in the Y-direction, wherein the length L4 may be substantially greater than the width W4. The first cathode conductive via 3424 has a length L5 defined along the X-direction and a width W5 defined along the Y-direction, wherein the length L5 may be substantially greater than the width W5. The length L4 of the first cathode conductive lines 3422 is greater than the length L5 of the first cathode conductive via 3424. In some embodiments, the length L5 of the first cathode conductive via 3424 is greater than half the length L4 of the first cathode conductive lines 3422. The width W4 of the first cathode conductive lines 3422 may be substantially greater than the width W5 of the first cathode conductive via 3424. In some embodiments, the length L4 of the first cathode conductive lines 3422 is substantially equally to the length L1 of the first anode conductive lines 3222, the width W4 of the first cathode conductive lines 3422 is substantially equally to the width W1 of the first anode conductive lines 3222. In some embodiments, the length L5 of the first cathode conductive via 3424 is substantially equally to the length L2 of the first anode conductive via 3224, and the width W4 of the first cathode conductive lines 3422 is substantially equally to the width W2 of the first anode conductive via 3224.

In some embodiments, the second cathode member 344 includes a plurality of second cathode conductive lines 3442 and a plurality of second cathode conductive vias 3444. The second cathode conductive lines 3442 are substantially equally spaced and extend along the Y-direction. The second cathode conductive lines 3442 are vertically spaced apart from each other in the Z-direction. Each of the second cathode conductive vias 3444 connects two neighboring second cathode conductive lines 3442. The second cathode conductive vias 3444 have a length L6 in the Y-direction and a width W6 in the X-direction, wherein the length L6 may be substantially equal to the width W6.

In some embodiments, the second anode member 324 is spaced apart from the second cathode member 344 in the X-direction, and the first anode members 322 and the first cathode members 342 are between the second anode member 324 and the second cathode member 344. The first anode members 322 may be connected to the second anode member 324 and separated from the second cathode member 344. In some embodiments, the first anode members 322 are separated from the second cathode member 344 by a distance D1. The first cathode members 342 may be connected to the second cathode member 344 and separated from the second anode member 324 by the distance D1. For example, the first cathode members 342 may be separated from the second anode member 324 by the distance D1. In some embodiments, the first anode members 322 are interdigitated with the first cathode members 342 when viewed from a top perspective and when viewed from a cross-sectional view.

Referring to FIG. 5, in some embodiments, the first anode members 322 and the first cathode members 342 are separated apart from each other. The first anode members 322 and the first cathode members 342 are arranged in an array along the Y-direction and along the Z-direction. In some embodiments, the first anode members 322 and the first cathode members 342 are arranged in an array in the Y-Z plane. The array may be an M×N array, where M and N are both positive integers and may be the same or different, e.g., a 3×3 array. The first anode members 322 and the first cathode members 342 are parallel to each other and equally spaced apart. The first anode members 322 may be horizontally and vertically staggered from the first cathode members 342. For example, one of the first anode members 322 is between two of the first cathode members 342, or vice versa.

Referring again to FIG. 1, one or more insulating layers (e.g., the insulating layers 210 to 220 or the insulating layers 214 to 224) are used as a capacitor dielectric of the capacitor component 30. In some embodiments, the insulating layers 210 to 220 or the insulating layers 214 to 224 fill spaces between the anode assembly 32 and the cathode assembly 34, between the first anode members 322 and the second anode member 324, and between the first cathode members 342 and the second cathode member 344. The insulating layers 210 to 220 or the insulating layers 214 to 224 may further laterally surround the capacitor components 30. Each of the capacitor components 30 has a capacitance. In some embodiments, the capacitance is a function of several factors, such as dielectric constants of the insulating layers 210 to 220 or the insulating layers 214 to 224, overlapping surface areas of the anode assembly 32 and the cathode assembly 34, and the distance D1. For example, a higher dielectric constant of the insulating layer may provide a greater capacitance. For another example, a greater capacitance may be achieved by increasing the overlapping areas of the first anode members 322 and the first cathode members 342 or reducing the distance D1.

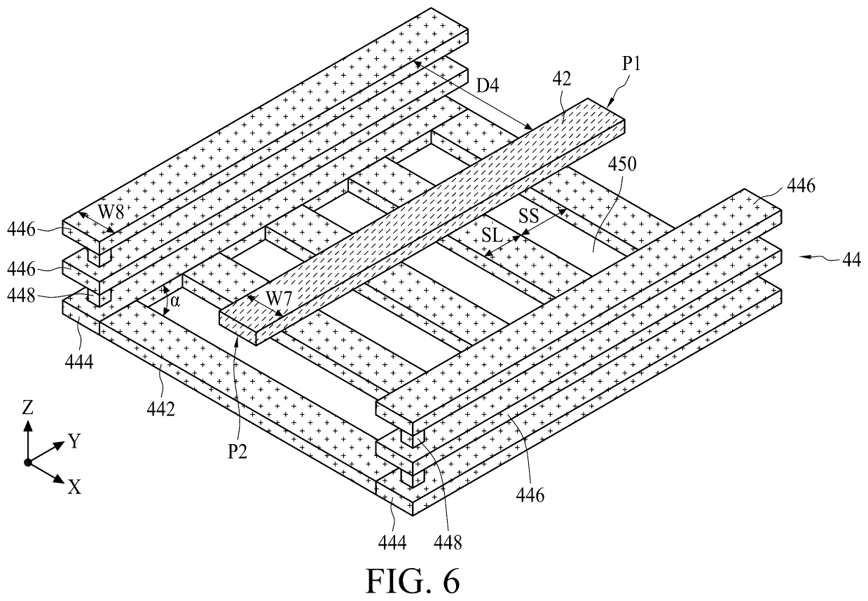

Referring to FIG. 6, in some embodiments, the inductor component 40 includes a signal line 42 and a shielding assembly 44, wherein the signal line 42 is electrically insulated from the shielding assembly 44. The signal line 42 extends in the Y-direction. An electrical signal may be propagated from a first port P1 to a second port P2 of the signal line 42. The shielding assembly 44 may surround the signal line 42 to provide a shield function such that the signal line 42 is electrically shielded from the capacitor component 30 under the signal line 42. Hence, an induced energy loss is substantially reduced and a quality factor of the capacitor component 30 is substantially increased. The shielding assembly 44 is used to detune the capacitor component 30 and the inductor component 40 from resonance. The signal line 42 may be further electrically shielding from the interconnect structure 25 proximal to the signal line 42. In some embodiments, the shielding assembly 44 has a U-shaped cross-sectional view. In some embodiments, the shielding assembly 44 is electrically grounded. In alternative embodiments, the shielding assembly 44 is floating.

In some embodiments, the shielding member 44 provides a return path for signals propagating in the signal line 42. The shielding assembly 44 may include a plurality of first shielding members 442, a pair of second shielding members 444, a plurality of third shielding members 446, and a plurality of conductive vias 448. The first shielding members 442 may have a strip shape. The first shielding members 442 are parallel to each other and equally spaced apart. The signal line 42 and the first shielding members 442 extend in different directions. The second shielding members 444, the third shielding members 446 may extend in a same direction. In some embodiments, the signal line 42 extends along the Y-direction, and the first shielding members 442 extend along a direction not parallel to the Y-direction. An included angle α formed between the signal line 42 and each first shielding member 442 is greater than about 5 degrees. For example, the first shielding members 442 may extend along the X-direction orthogonal to the Y-direction. The second shielding members 444 and the third shielding members 446 may extend along the Y-direction.

The first shielding members 442 and the second shielding members 444 may be disposed in a same tier of the interconnect layer 104 shown in FIG. 1. Each of the first shielding members 442 may have a width SL in the Y-direction and may be spaced from a neighboring first shielding member 442 by a distance SS in the Y-direction. The width SL of each first shielding member 442 may be equal to or different from the distance SS between adjacent first shielding members 442.

The pair of second shielding members 444 are spaced apart from one another, and the first shielding members 442 connect one of the second shielding members 444 to another one of the second shielding members 444. Two of the first shielding members 442 farthest from each other and the pair of second shielding members 444 collectively form a substantially rectangular perimeter, as seen from a top-view perspective. In some embodiments, the first shielding members 442 and the second shielding members 444 are integrally formed. Since the first shielding members 442 immediately under the signal line 42 are not parallel to the signal line 42 and the second shielding members 444 are parallel to the signal line 42, the shielding assembly 40 provide a lower impedance return path for the signals to ground through the second shielding members 444 than through the first shielding members 442. Accordingly, a return path for the signals propagating in the signal line 42 may be the second shielding members 444. The first shieling members 442 are used to avoid or at least minimize inductive coupling from the signal lines 42 to the capacitor component 30. The first shieling members 442 and the second shielding members 444 may provide slow-wave effects, resulting in a more efficient utilization of valuable chip area.

In some embodiments, some of the third shielding members 446 are disposed over and vertically aligned with one of the second shielding members 444, and others of the third shielding members 446 are disposed over and vertically aligned with another of the second shielding members 444. The third shielding members 446 and the second shielding member 444 thereunder may be substantially equally spaced. Some of the conductive vias 448 connect neighboring pairs of the third shielding members 446, and others of the conductive vias 448 connect a second shielding member 444 to an adjacent third shielding member 446.

Referring to FIGS. 1 and 6, in some embodiments, the signal line 42 and two of the third shielding members 446 farthest from the second shielding members 444 are disposed in a same tier of the interconnect layer 104. The signal line 42 may be arranged between the pair of third shielding members 446. The signal line 42 may be spaced apart from each third shielding member 446 by a distance D4. An impedance of the inductor component 40 may be tuned by adjusting the distance D4 between each of the second shielding members 444 and the signal line 42. In some embodiments, the distance D4 is in a range between 1 μm and 100 μm. The signal line 42 has a width W7, the third shielding members 446 have a width W8, and the width W7 may be substantially equal to the width W8.

Referring again to FIG. 1, the capacitor components 30 and the inductor components 40 may be made of at least one metallic material. In some embodiments, the anode assembly 32 and the cathode assembly 34 of the capacitor components 30, the signal line 42 and the shielding assembly 44 are made of a same metallic material. In some embodiments, the capacitor components 30 and the inductor components 40 include a carbon-containing conductive material, such as carbon-containing copper or carbon-containing manganese. The conductive lines 252 and the conductive vias 254 of the interconnect structure 25 may include the carbon-containing conductive material due to the capacitor components 30 and the inductor components 40 being formed simultaneously with the interconnect structure 25. In some embodiments, a concentration of carbon in the carbon-containing conductive material is greater than about 5%. The interconnect structure 25, the capacitor components 30, and the inductor components 40 may be formed in the insulating layers 210 to 234 by photolithography and etching operations to form via holes and trenches, and by deposition, sputtering, plating, or combinations thereof to fill the via holes and the trenches with the conductive material.

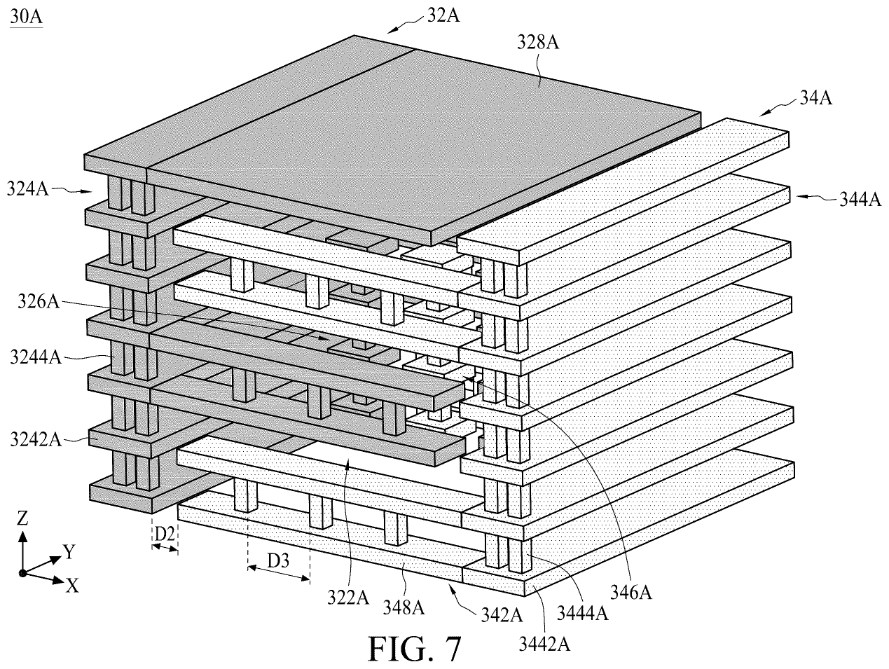

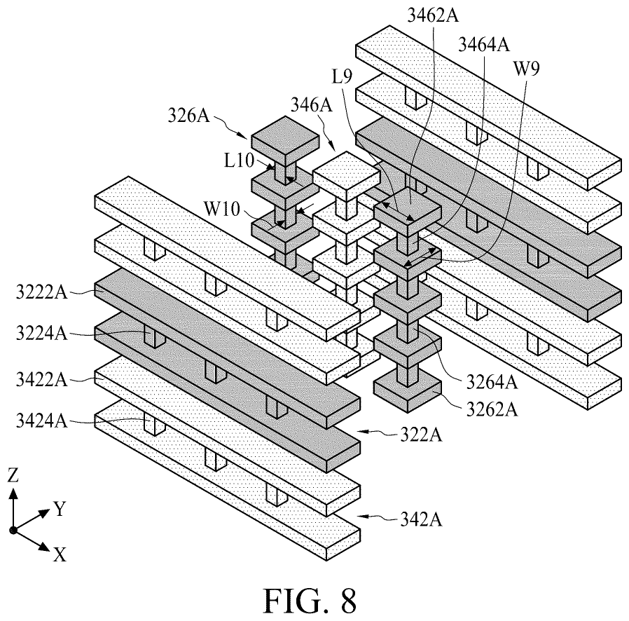

FIG. 7 is a schematic perspective view of a capacitor component 30A, in accordance with some embodiments of the present disclosure, and FIG. 8 is a schematic perspective view of a portion of the capacitor component 30A illustrating some embodiments of the present disclosure that include a plurality of first anode members 322A, a plurality of third anode members 326A, a plurality of first cathode members 342A, and a third cathode member 346A of the capacitor component 30A. Referring to FIGS. 7 and 8, in some embodiments, the capacitor component 30A includes an anode assembly 32A and a cathode assembly 34A. The anode assembly 32A is separated from and electrically insulated from the cathode assembly 34A. Spaces between the anode assembly 32A and the cathode assembly 34A may be filled with one or more insulating layers.

In some embodiments, the anode assembly 32A is separated from the cathode assembly 34A by a distance D2 in the X-direction. The anode assembly 32A may include a plurality of first anode members 322A, a second anode member 324A, a plurality of third anode members 326A, and a fourth anode member 328A. The cathode assembly 34A may include a plurality of first cathode members 342A, a second cathode member 344A, a third cathode member 346A, and a fourth cathode member 348A.

Each of the first anode members 322A includes a pair of first anode conductive lines 3222A and a plurality of first anode conductive vias 3224A. In some embodiments, the first anode conductive lines 3222A extend along the X-direction and are spaced apart from one another in the Z-direction. The pair of first anode conductive lines 3222A are connected by the first anode conductive vias 3224A. In some embodiments, the first anode conductive vias 3224A provide electrical connection between the first anode conductive lines 3222A in different tiers of the interconnect layer 104 (shown in FIG. 1). In some embodiments, a neighboring pair of the first anode conductive vias 3224A are spaced apart by a distance D3, which is greater than a distance D2 between the anode assembly 32A and the cathode assembly 34A.

Referring to FIG. 7, in some embodiments, the second anode member 324A includes a plurality of second anode conductive lines 3242A and a plurality of second anode conductive vias 3244A. The second anode conductive lines 3242A are substantially equally spaced and may extend along the Y-direction. The second anode conductive lines 3242A are vertically spaced apart from each other in the Z-direction. The second anode conductive vias 3244A connect neighboring pairs of the second anode conductive lines 3242A in different tiers of the interconnect layer 104 (shown in FIG. 1).

The second cathode member 344A may include a plurality of second cathode conductive lines 3442A and a plurality of second cathode conductive vias 3444A. In some embodiments, the second cathode conductive lines 3442A are substantially equally spaced and extend along the Y-direction. The second cathode conductive lines 3442A may be vertically spaced apart from each other in the Z-direction. In some embodiments, the second cathode conductive vias 3444A connect neighboring pairs of the second cathode conductive lines 3442A.

Referring to FIG. 8, in some embodiments, each of the first cathode members 342A includes a pair of first cathode conductive lines 3422A and a plurality of first cathode conductive vias 3424A. In some embodiments, the first cathode conductive lines 3422A extend along the X-direction and are spaced apart from one another in the Z-direction. The first cathode conductive vias 3424A may be disposed between and connected to the first cathode conductive lines 3422A disposed in different tiers of the interconnect layers 104 (shown in FIG. 1).

The third anode members 326A may include a plurality of third anode conductive lines 3262A and a plurality of third anode conductive vias 3264A. In some embodiments, the third anode conductive lines 3262A are spaced apart from one another in the Y-direction, and each of the third anode conductive vias 3264A connects an adjacent pair of the third anode conductive lines 3262A. The third anode conductive lines 3262A have a length L9 in the X-direction and a width W9 in the Y-direction, wherein the length L9 may be substantially equal to the width W9. The third anode conductive vias 3264A have a length L10 in the X-direction and a width W10 in the Y-direction, wherein the length L10 may be substantially equal to the width W10. In some embodiments, the length L9 of the third anode conductive lines 3262A is greater than the length L10 of the third anode conductive vias 3264A, and the width W9 of the third anode conductive lines 3262A is greater than the width W10 of the third anode conductive vias 3264A.

The third cathode members 346A may have a configuration same as a configuration of the third anode members 326A. In some embodiments, the third cathode members 346A include a plurality of third cathode conductive lines 3462A and a plurality of third cathode conductive vias 3464A. The third cathode conductive lines 3462A are spaced apart from one another in the Z-direction, and each of the third cathode conductive vias 3464A connects an adjacent pair of the third cathode conductive lines 3462A.

The third anode members 326A and the third cathode member 346A are arranged in line in the X-direction and separated from one another. The third cathode member 346A may be interleaved with the third anode members 326A. For example, a third cathode member 346A is between two of the third anode members 326A. In some embodiments, the third anode members 326A and the third cathode member 346A are alternating in the X-direction, and one of the third cathode member 346A is between two of the third anode members 326A. In some embodiments, the first anode members 322A and the first cathode members 342A are disposed on opposite sides along the Y-direction of the third anode members 326A and the third cathode member 346A. The first anode members 322A and the first cathode members 342A may be aligned in the Z-direction, and the first anode members 322A may be interleaved with the first cathode members 342A.

Referring back to FIG. 7, the fourth anode member 328A and the fourth cathode member 348A are disposed on opposite sides along the Z-direction of the third anode members 326A and the third cathode member 346A. The fourth anode member 328A, a topmost layer of the second anode member 324A, and a topmost layer of the second cathode members 344A may be disposed in a same tier of the interconnect layer 104 (shown in FIG. 1). The fourth cathode member 348A, a bottommost layer of the second anode member 324A, and a bottommost layer of the second cathode members 344A may be disposed in a same tier of the interconnect layer 104 (shown in FIG. 1). The third anode members 326A may be electrically coupled to the fourth anode member 328A, and the third cathode member 346A may be electrically coupled to the fourth cathode member 348A.

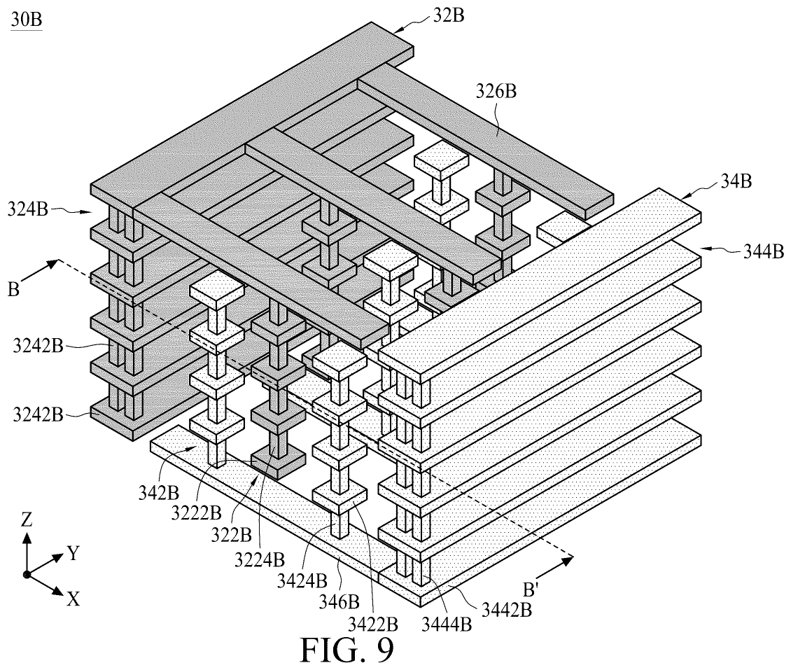

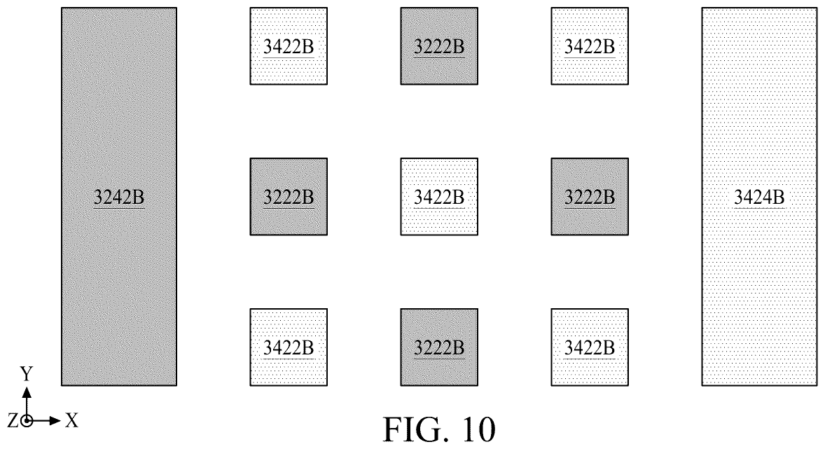

FIG. 9 is a schematic perspective view of a capacitor component 30B, in accordance with some embodiments of the present disclosure, and FIG. 10 is a cross-sectional view along a line B-B′ of the capacitor component in FIG. 9. Referring to FIGS. 9 and 10, in some embodiments, the capacitor component 30B includes an anode assembly 32B and a cathode assembly 34B. The anode assembly 32B is separated from and electrically insulated from the cathode assembly 34B. In some embodiments, spaces between the anode assembly 32B and the cathode assembly 34B are filled with one or more insulating layers.

The anode assembly 32B may include a plurality of first anode members 322B, a second anode member 324B, and a plurality of third anode members 326B. The cathode assembly 34B may include a plurality of first cathode members 342B, a second cathode member 344B, and a plurality of third cathode members 346B. Each of the first anode members 322B includes alternating first anode conductive lines 3222B and first anode conductive vias 3224B. In some embodiments, neighboring pairs of the first anode conductive lines 3222B are connected by one of the first anode conductive vias 3224B. The first anode conductive vias 3224B provide electrical connection between the first anode conductive lines 3222B in different tiers of the interconnect layer 104 (shown in FIG. 1).

In some embodiments, each of the first cathode members 342B includes alternating first cathode conductive lines 3422B and first cathode conductive vias 3424B. Neighboring pairs of the first cathode conductive lines 3422B may be connected by one of the first cathode conductive vias 3424B. The first cathode conductive vias 3424B provide electrical connection between the first cathode conductive lines 3422B in different tiers of the interconnect layer 104 (shown in FIG. 1).

The second anode member 324B and the second cathode member 344B may be disposed at opposite sides along the X-direction of the third anode members 326B and the third cathode members 346B. In some embodiments, the second anode member 324B includes a plurality of second anode conductive lines 3242B and a plurality of second anode conductive vias 3244B. The second anode conductive lines 3242B are substantially equally spaced and may extend along the Y-direction. The second anode conductive lines 3242B are vertically spaced apart from each other in the Z-direction. Each of the second anode conductive vias 3244B connects a neighboring pair of the second anode conductive lines 3242B.

The second cathode member 344B may include a plurality of second cathode conductive lines 3442B and a plurality of second cathode conductive vias 3444B. In some embodiments, the second cathode conductive lines 3442B are substantially equally spaced and extend along the Y-direction. The second cathode conductive lines 3442B may be vertically spaced apart from each other in the Z-direction. In some embodiments, each of the second cathode conductive vias 3444B connects a neighboring pair of the second cathode conductive lines 3442B.

In some embodiments, the third anode members 326B and the third cathode members 346B are disposed on opposite sides along the Z-direction of the first anode members 322B and the first cathode members 342B. The third anode members 326B and a topmost layer of the second anode member 324B may be disposed at a same tier of the interconnect layer 104 (shown in FIG. 1), and the third cathode members 346B and a bottommost layer of the second cathode member 344B may be disposed at a same tier of the interconnect layer 104. The third anode members 326B and the third cathode members 346B extend in the X-direction and are parallel to each other. The third anode members 326B may be connected to one or more of the first anode members 322B. The third cathode members 346B may be connected to one or more of the first cathode members 342B. In some embodiments, a quantity of the first anode conductive lines 3222B is equal to a quantity of the first anode conductive vias 3224B, some of the third anode conductive vias 3264B connect neighboring pairs of the first anode conductive vias 3224B, and others of the third anode conductive vias 3264B connect the first anode conductive vias 3224B to the adjacent third anode members 326B. Some of the third cathode conductive vias 3464B connect neighboring pairs of the first anode conductive vias 3224B, and others of the third cathode conductive vias 3464B connect the first anode conductive vias 3224B to the adjacent third cathode members 346B. The capacitor components 30, 30A, and 30B arranged in different configurations may have different overlapping surface areas of the anode assembly and the cathode assembly. Therefore, the capacitor component 30, 30A/30B having the same dimension along the X-direction, the Y-direction, and the Z-direction may have different capacitances.

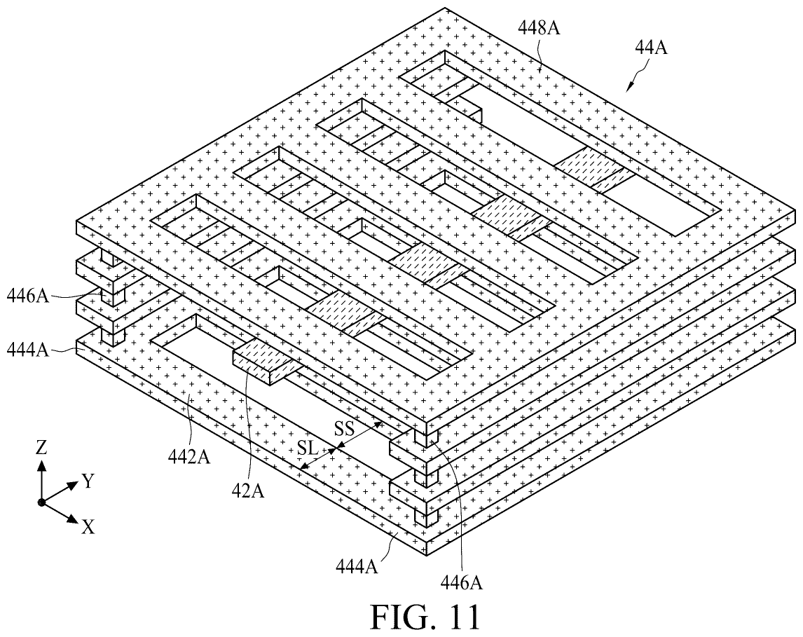

FIG. 11 is a schematic perspective view of an inductor component 40A, in accordance with some embodiments of the present disclosure. Referring to FIG. 11, the inductor component 40A includes a signal line 42A and a shielding assembly 44A. The signal line 42A extends in the Y-direction. An electrical signal may be propagated through the signal line 42A. The shielding assembly 44A may surround the signal line 42A to provide a shielding function such that the signal line 42A is electrically shielded from the capacitor component 30A under the signal line 42A and the interconnect structure 25 (shown in FIG. 1) proximal to and above the signal line 42A. Hence, an induced energy loss is substantially reduced and a quality of the capacitor component 30 is substantially increased. In some embodiments, the shielding assembly 44A is electrically grounded.

The shielding assembly 44A may include a plurality of first conductive strips 442A, a plurality of second conductive strips 444A, a plurality of third conductive strips 446A, and a plurality of conductive vias 448A. Each of the first conductive strips 442A may have a width SL in the Y-direction and may be spaced apart from a neighboring first conductive strip 442A by a distance SS in the Y-direction. In some embodiments, the first conductive strips 442A are disposed at opposite sides along the Z-direction of the signal line 42A.

Each of the first conductive strips 442A includes a first terminal connected to one of the second conductive strips 444A and a second terminal connected to another of the second conductive strips 444A. Two of the first conductive strips 442A farthest from each other and two of the second conductive strips 444A connected thereto collectively form a substantially rectangular perimeter, as seen from a bottom-view perspective. The first conductive strips 442A and two of the second conductive strips 444A connected to the first conductive strips 442A may be integrally formed.

In some embodiments, the third conductive strips 446A are disposed between and vertically aligned with two of the second conductive strips 444A stacked in the Z-direction. The third conductive strips 446A and the second conductive strip 444A may be substantially equally spaced in the Z-direction. Some of the conductive vias 448A connect neighboring pairs of the third conductive strips 446A, and others of the conductive vias 448A connect one of the third conductive strips 446A to an adjacent second conductive strip 444A.

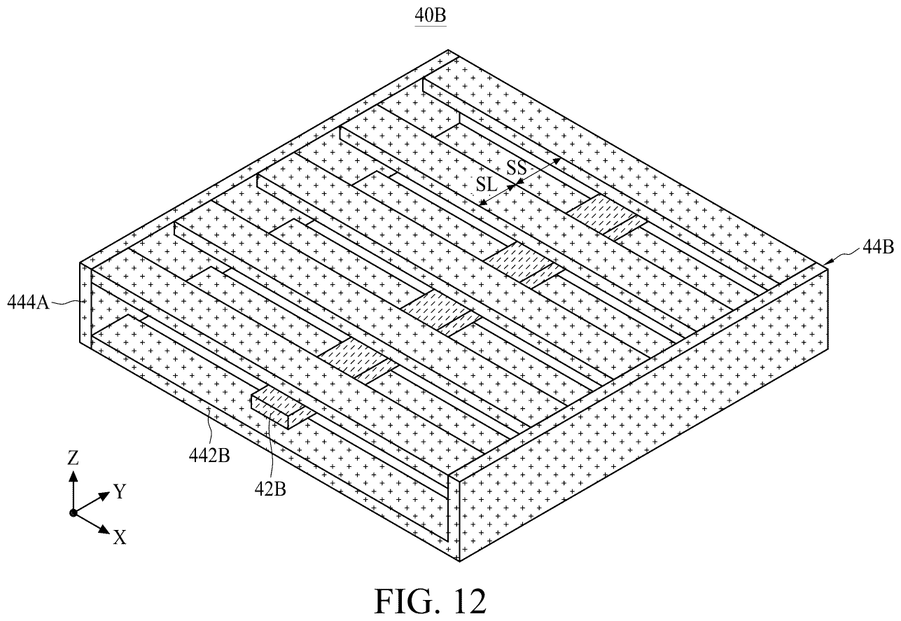

FIG. 12 is a schematic perspective view of an inductor component 40B, in accordance with some embodiments of the present disclosure. Referring to FIG. 12, the inductor component 40B includes a signal line 42B and a shielding assembly 44B. The signal line 42B extends in the Y-direction. An electrical signal may be propagated through the signal line 42B. The shielding assembly 44B may surround the signal line 42B to provide a shielding function such that the signal line 42B is electrically shielded from the capacitor component 30 under the signal line 42B and the interconnect structure 25 (shown in FIG. 1) proximal to and above the signal line 42B. Hence, an induced energy loss is substantially reduced and a quality of the capacitor component 30 is substantially increased. In some embodiments, the shielding assembly 44B is electrically grounded.

The shielding assembly 44B may include a plurality of first shielding members 442B and a pair of second shielding members 444B. Each of the first shielding members 442B may have a width SL in the Y-direction and may be spaced from a neighboring shielding member 442B by a distance SS in the Y-direction. In some embodiments, the first shielding members 442B are disposed at opposite sides along the Z-direction of the signal line 42B. Each of the first shielding members 442B includes a first terminal connected to one of the second shielding members 444B and a second terminal connected to another of the second shielding members 444B.

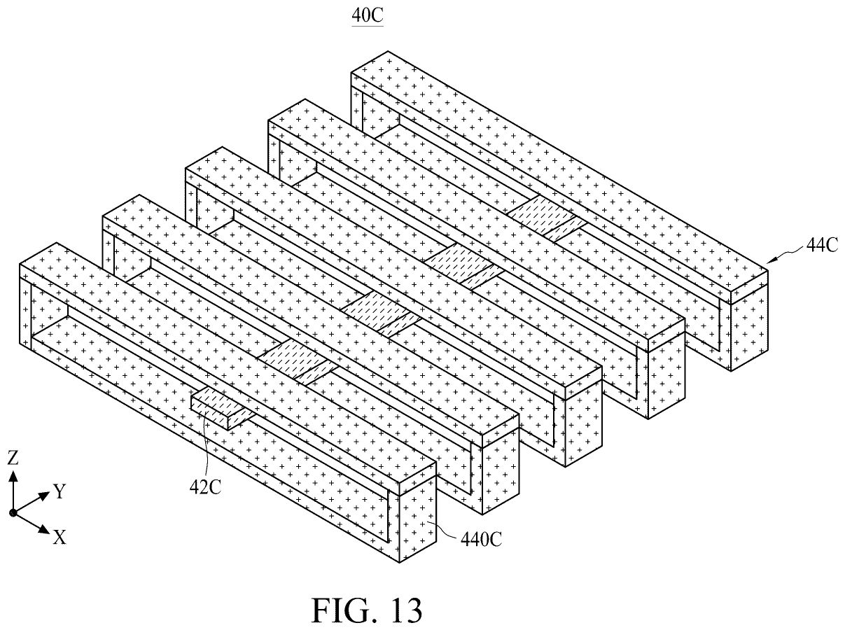

FIG. 13 is a schematic perspective view of an inductor component 40C, in accordance with some embodiments of the present disclosure. Referring to FIG. 12, the inductor component 40C includes a signal line 42C and a shielding assembly 44C. The signal line 42C extends in the Y-direction. An electrical signal may be propagated through the signal line 42C. The shielding assembly 44C may surround the signal line 42C to provide a shielding function such that the signal line 42C is electrically shielded from the capacitor component 30 under the signal line 42C and the interconnect structure 25 (shown in FIG. 1) proximal to and above the signal line 42C. Hence, an induced energy loss is substantially reduced and a quality of the capacitor component 30 is substantially increased. In some embodiments, the shielding assembly 44C is electrically grounded. In alternative embodiments, the shielding assembly 44C is floating. The shielding member 44C may include a plurality of ring members 440C extending along X-direction and spaced from each other along the Y-direction. The ring members 440C are arranged around the signal line 42C.

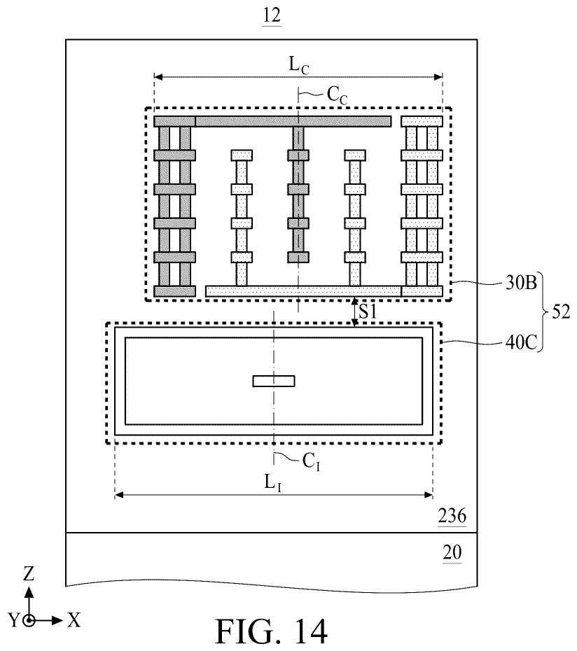

FIG. 14 is a schematic cross-sectional view of a semiconductor device 12, in accordance with some embodiments of the present disclosure. Referring to FIG. 14, in some embodiments, the semiconductor device 12 includes a stacked structure 52 including a capacitor component (such as the capacitor component 30B illustrated in FIG. 9) and an inductor component (such as the inductor component 40C illustrated in FIG. 13). The capacitor component 30B and the inductor component 40C may be disposed in one or more insulating layers 236 over a substrate 20. In some embodiments, the capacitor component 30B is disposed over the inductor component 40C. The capacitor component 30B and the inductor component 40C may be vertically separated apart by an interval S1. The capacitor component 30B may fully overlap the inductor component 40C. In some embodiments, the capacitor component 30B has a length L_{C} in the X-direction, the inductor component 40C has a length L_{I} in the X-direction, and the length L_{C} is greater than the length L_{I}. The capacitor component 30B has a central line C_{C} along the Z-direction, the inductor component 40C has a central line C_{I} along the Z-direction, and the central line C_{C} may be aligned with the central line C_{I}.

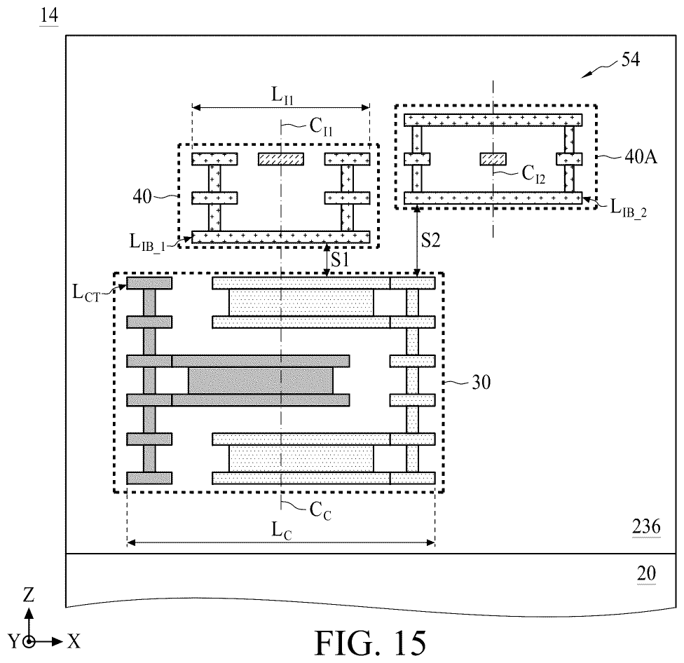

FIG. 15 is a schematic cross-sectional view of a semiconductor device 14, in accordance with some embodiments of the present disclosure. Referring to FIG. 15, in some embodiments, the semiconductor device 14 includes a stacked structure 54. The stacked structure 54 includes a capacitor component (such as the capacitor component 30 illustrated in FIG. 4) and a plurality of inductor components (such as the inductor component 40 illustrated in FIG. 6 and the inductor component 40A illustrated in FIG. 11) stacked over the capacitor component 30. The capacitor component 30 and the inductor components 40 and 40A may be disposed in one or more insulating layers 236 over a substrate 20.

The inductor component 40 may fully overlap the capacitor component 30, and the inductor component 40A may partially overlap the capacitor component 30. In some embodiments, the capacitor component 30 has a length L_{C} in the X-direction, the inductor component 40 has a length L_{I1} in the X-direction, and the length L_{C} is greater than the length Ln. The inductor component 40A may have a length L_{I2} in the X-direction, and the length L_{I2} may be greater than or less than the length L_{C} or L_{I1}. In some embodiments, the capacitor component 30 has a central line C_{C} along the Z-direction, the inductor component 40 has a central line C_{I1} along the Z-direction, the central line C_{C} may be aligned with the central line C_{I1}. The inductor component 40A has a central line C_{I2} along the Z-direction, and the central line C_{I2} may be offset from the central line C_{C}.

The capacitor component 30 includes a topmost layer L_{CT}, the inductor component 40 includes a bottommost layer L_{IB_1}, and the inductor component 40A includes a bottommost layer L_{IB_2}. The inductor components 40 and 40A may be vertically separated from the capacitor component 30 by a same or different intervals. For example, the topmost layer L_{CT} of the capacitor component 30 and the bottommost layer L_{IB_1} of the inductor component 40 may be vertically separated apart by an interval S1, and topmost layer L_{CT} of the capacitor component 30 and the bottommost layer L_{IB_2} of the inductor component 40A may be vertically separated apart by an interval S2 greater than the interval S1.

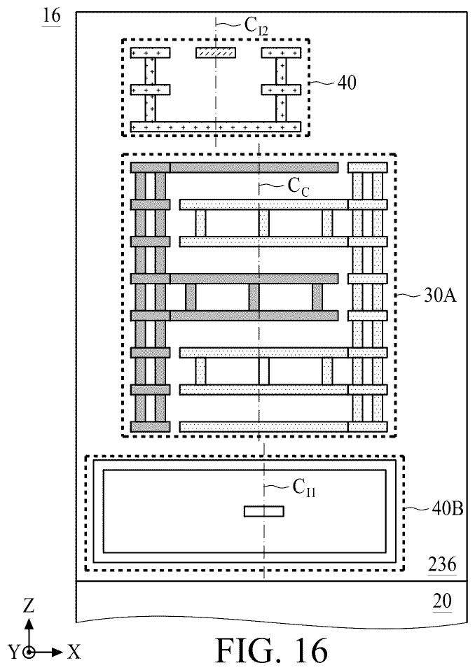

FIG. 16 is a schematic cross-sectional view of a semiconductor device 16, in accordance with some embodiments of the present disclosure. Referring to FIG. 16, in some embodiments, the semiconductor device 16 includes a substrate 20 and a stacked structure 56 disposed over the substrate 20. The stacked structure 56 includes a capacitor component (such as the capacitor component 30A illustrated in FIG. 7) and a plurality of inductor components (such as the inductor component 40 illustrated in FIG. 6 and the inductor component 40B illustrated in FIG. 12) stacked along the Z-direction, and the capacitor component 30A is between the inductor components 40 and 40B. The capacitor component 30 and the inductor components 40 and 40B may be surrounded by one or more insulating layers 236 over the substrate 20.

The inductor component 40 may fully overlap the capacitor component 30A, and the capacitor component 30A may fully overlap the inductor component 40. The capacitor component 30A has a central line C_{C} along the Z-direction, the inductor component 40 has a central line C_{I1} along the Z-direction, and the inductor component 40B has a central line C_{I2} along the Z-direction, wherein the central line C_{C} may be offset from the central line C_{I1}, and the central line C_{C} may be offset from the central line C_{I2}.

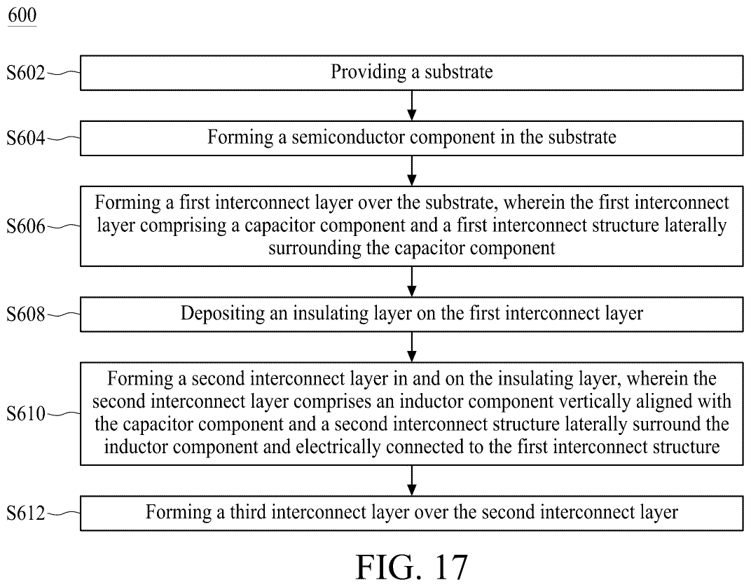

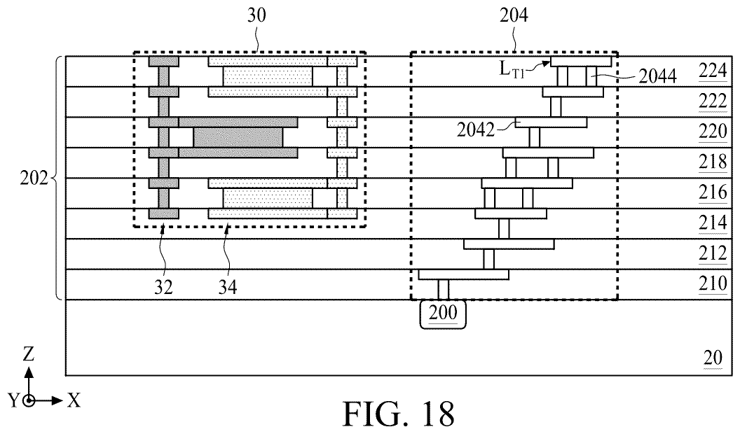

FIG. 17 is a flowchart of a method 600 of manufacturing a semiconductor device 10, in accordance with some embodiments of the present disclosure. FIGS. 18 to 20 are cross-sectional views of intermediate stages of the method 600 of manufacturing the semiconductor device 10, in accordance with some embodiments of the present disclosure. In the following description, the manufacturing stages shown in FIGS. 18 to 20 are discussed with reference to the process steps shown in FIG. 17. It should be understood that additional steps can be provided before, during, and after the steps shown in FIG. 17, and some of the steps described below can be replaced or eliminated, for additional embodiments of the method 600. The order of the steps may be changed.

Referring to FIGS. 17 and 18, a substrate 20 is provided in accordance with step S602. The substrate 20 may be a part of a wafer or a bulk substrate formed of a bulk material. In some embodiments, the substrate 20 includes a semiconductor material. In some embodiments, the substrate 200 is a silicon substrate.

Subsequently, one or more semiconductor components 200 are formed in and/or on the substrate 20 in accordance with step S604 in FIG. 17. The semiconductor components 200 (e.g., transistors, resistors, or the like) are formed in and/or on the substrate 20.

Subsequently, a first interconnect layer 202 including a capacitor component 30 and a first interconnect structure 204 is formed over the substrate 20 and the semiconductor components 200 in accordance with step S606 in FIG. 17. In some embodiments, the capacitor component 30 comprising an anode assembly 32 and a cathode assembly 34 electrically insulated from each other. Each of the anode assembly 32, the cathode assembly 34, and the first interconnect structure 204 may be formed by alternating conductive lines 2042 and conductive vias 2044 that are electrically connected to each other. In some embodiments, some of the conductive lines 2042 and the conductive vias 2044 of the first interconnect structures 204 are electrically connected to the semiconductor components 200. Some of the conductive lines 2042 and conductive vias 2044 of the first interconnect structures 204 may be electrically connected to the capacitor component 30. The capacitor component 30 may be electrically connected to the semiconductor component through the first interconnect structure 204.

The conductive lines 2042 and the conductive vias 2044 may be laterally surrounded by one or more insulating layers 210-224. In some embodiments, the conductive lines 2042 and the conductive vias 2044 is formed by a single damascene operation or a dual damascene operation. The damascene operation may include performing a lithography and etching process to form a plurality of trenches in one of the insulating layers 210-224, filling the trenches with a carbon-containing metallic material, and performing a planarization to remove excess the carbon-containing metallic material to thereby form the interconnect layer 202. Topmost conductive lines L_{T1} of the first interconnect layer 202 and the insulating layer 224 may have substantially planar surfaces.

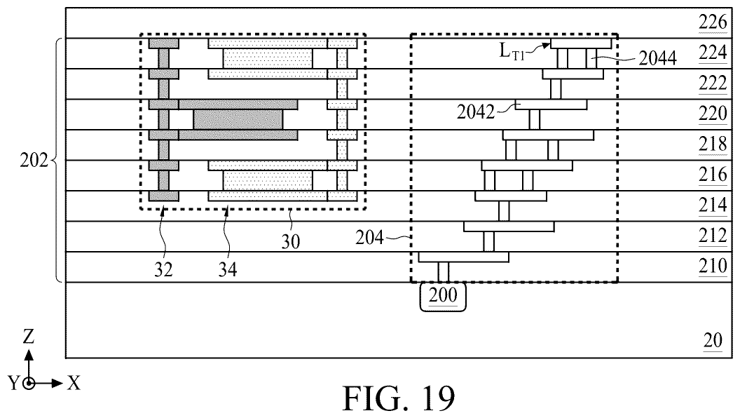

Referring to FIG. 19, an insulating layer 226 is deposited on the first interconnect layer 202 in accordance with step S608 in FIG. 17. The insulating layer 226 is deposited to cover the topmost conductive lines L_{T1} of the first interconnect layer 202 and the insulating layer 224. The insulating layer 226 may be formed on the first interconnect layer 202 and the insulating layer 224 by performing by a chemical vapor deposition (CVD) operation.

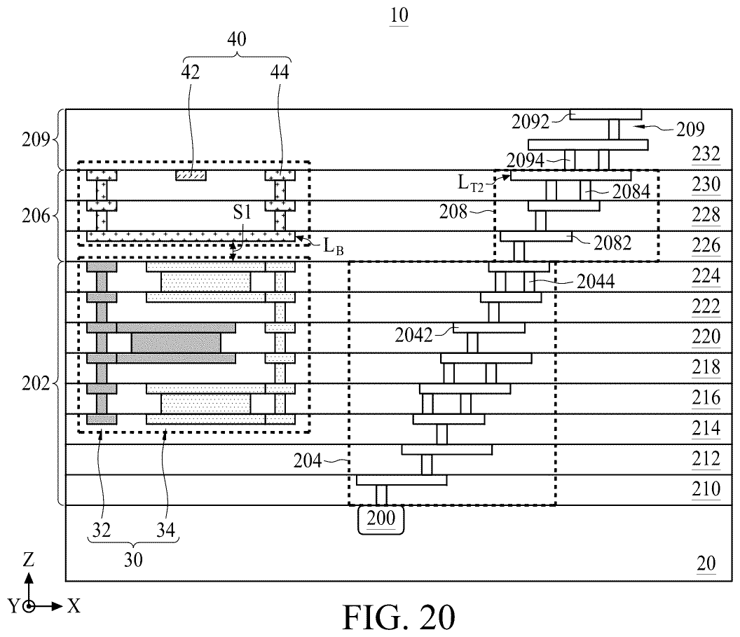

Referring to FIG. 20, a second interconnect layer 208 including an inductor component 40 and a second interconnect structure 208 is formed in and/or on the insulating layer 206 in accordance with step S610 in FIG. 17. In some embodiments, the inductor component 40 is disposed over the capacitor component 30 and vertically aligned with the capacitor component 30. The inductor component 40 may be laterally surrounded by the second interconnect structure 208. The inductor component 40 includes a signal line 42 disposed over the capacitor component 30 and a shielding assembly 44 between the signal line 42 and the capacitor component 30. Each of the shielding assembly 44 and the second interconnect structure 208 may be formed by alternation conductive lines 2082 and conductive vias 2084 that are electrically connected to each other. The conductive lines 2082 and conductive vias 2084 may be further laterally surrounded by one or more insulating layers 228 and 230. The conductive lines 2082 and the conductive vias 2084 may include carbon-containing metallic material and may be formed by a single damascene operation or a dual damascene operation. In some embodiments, topmost conductive lines L_{T2} of the second interconnect layer 208 and the insulating layer 230 have substantially planar surfaces. In some embodiments, some of the conductive lines 2082 and the conductive vias 2084 are disposed in the insulating layer 206, so that the second interconnect structure 208 is connected to the first interconnect structure 204. One or more bottommost conductive lines L_{B} of the first interconnect layer 202 may be disposed in the insulating layer 206.

Subsequently, one or more third interconnect layers 209 are formed over the second interconnect layer 208 in accordance with step S612 in FIG. 17. Accordingly, the semiconductor device 10 is completely formed. The third interconnect layer 209 may include an insulating layer 232 and alternating conductive lines 2092 and conductive vias 2094 formed in the insulating layer 232 and electrically connected to the second interconnect structure 208. The third interconnect layer 209 may be electrically connected to an external circuit (not shown) outside the semiconductor device 10. The conductive lines 2092 and the conductive vias 2094 may include carbon-containing metallic material and may be formed by a single damascene operation or a dual damascene operation.

In accordance with some embodiments of the present disclosure, a semiconductor device includes: a substrate, a capacitor component, an inductor component, and an interconnect structure. The capacitor component is disposed over the substrate and includes an anode assembly and a cathode assembly electrically insulated from the anode assembly. The inductor component is disposed on and vertically aligned with the capacitor component, wherein the inductor component includes a signal line and a shielding assembly between the signal line and the capacitor component. The interconnect structure is disposed over the substrate and surrounds the capacitor component and the inductor component.

In accordance with some embodiments of the present disclosure, a semiconductor device includes a device layer and an interconnect layer. The device layer includes a semiconductor component. The interconnect layer is disposed over the device layer and includes a capacitor component, an inductor component, and an interconnect structure. The capacitor component includes an anode assembly and a cathode assembly electrically insulated from the anode assembly. The inductor component is vertically overlapping the capacitor component and includes a signal line and a shielding assembly between the signal line and the capacitor component. The interconnect structure surrounds the capacitor component and the inductor component and includes alternating conductive lines and conductive vias electrically coupled to the semiconductor component.

In accordance with some embodiments of the present disclosure, a method of manufacturing a semiconductor device includes step of providing a substrate; forming a first interconnect layer over the substrate, wherein the first interconnect layer comprising a capacitor component and a first interconnect structure laterally surrounding the capacitor component; and forming a second interconnect layer over the first interconnect layer, wherein the second interconnect layer comprises an inductor component vertically aligned with the capacitor component and a second interconnect structure laterally surround the inductor component and electrically connected to the first interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a capacitor component disposed over the substrate and comprising an anode assembly and a cathode assembly electrically insulated from the anode assembly;
an inductor component disposed over the substrate and at least partially overlapping the capacitor component from a top-view perspective, wherein the inductor component comprises a signal line extending in a first direction and a shielding assembly between the signal line and the capacitor component; and
an interconnect structure disposed over the substrate and surrounding the capacitor component and the inductor component.

2. The semiconductor device of claim 1, wherein the inductor component is vertically aligned with the capacitor component.

3. The semiconductor device of claim 1, wherein the shielding assembly comprises:
a plurality of first shielding members extending along a second direction and substantially equally spaced in a third direction, wherein the first direction is different from the second direction and the second direction is perpendicular to the third direction; and
a pair of second shielding members extending along the first direction and on opposite sides of the plurality of first shielding members, and the plurality of first shielding members connect one of the second shielding members to another second shielding member.

4. The semiconductor device of claim 3, wherein the shielding assembly further comprises:
a plurality of third shielding members vertically aligned with the second shielding members; and
a plurality of connectors connecting two neighboring third shielding members that are vertically aligned and connecting each of the second shielding members to an adjacent third shielding member.

5. The semiconductor device of claim 1, wherein the shielding assembly is further between the signal line and the interconnect structure.

6. The semiconductor device of claim 5, wherein the shielding assembly comprising a plurality of ring structure around the signal lines and equally spaced from each other along the first direction.

7. The semiconductor device of claim 1, wherein:
the anode assembly comprises a plurality of first anode members and the cathode assembly comprises a plurality of first cathode members, and
the plurality of first anode members and the plurality of first cathode members, separated apart from each other, are arranged in an array extending along the first direction and along a fourth direction that is perpendicular to the first direction, wherein the plurality of first anode members are horizontally and vertically staggered from the plurality of first cathode members.

8. The semiconductor device of claim 7, wherein:
the anode assembly further comprises a second anode member connected to the plurality of first anode members,
the cathode assembly further comprises a second cathode member connected to the plurality of first cathode members, and
the second anode member and the second cathode member are spaced apart from each other in a second direction, and the plurality of first anode members and the plurality of first cathode members are between the second anode member and the second cathode member.

9. The semiconductor device of claim 7, wherein:
the anode assembly further comprises a second anode member and a third anode member connecting the second anode member to the plurality of first anode members,
the cathode assembly further comprises a second cathode member and a third cathode member connecting the second cathode member to the plurality of first cathode members,
the second anode member and the second cathode member are spaced apart from each other in a second direction, the third anode member is separated from the third cathode member in the fourth direction, and the plurality of first anode members and the plurality of first cathode members are between the second anode member and the second cathode member and between the third anode member and the third cathode member.

10. The semiconductor device of claim 9, wherein:
the anode assembly further comprises a plurality of fourth anode members,
the cathode assembly further comprises a plurality of fourth cathode members, and
the plurality of fourth anode members and the plurality of fourth cathode members, alternating in a third direction, are on opposite sides, in the first direction, of the plurality of first anode members and the plurality of first cathode members.

11. The semiconductor device of claim 1, further comprising at least one insulating layer between the capacitor component and the inductor component.

12. The semiconductor device of claim 11, wherein the insulating layer is disposed over the substrate and around the capacitor component, the inductor component, and the interconnect structure.

13. A semiconductor device, comprising:
a device layer comprising a semiconductor component; and
an interconnect layer disposed over the device layer and comprising:
a capacitor component comprising an anode assembly and a cathode assembly electrically insulated from the anode assembly;
an inductor component vertically overlapping the capacitor component and comprising a signal line extending in a first direction and a shielding assembly between the signal line and the capacitor component; and
an interconnect structure surrounding the capacitor component and the inductor component and comprising alternating conductive lines and conductive vias electrically coupled to the semiconductor component.

14. The semiconductor device of claim 13, wherein the inductor component is vertically aligned with the capacitor component.

15. The semiconductor device of claim 13, wherein the interconnect layer further comprises an insulating layer separating the anode assembly and the cathode assembly of the capacitor component, separating the signal line and the shielding assembly of the inductor component, and separating the capacitor component from the inductor component.

16. The semiconductor device of claim 13, wherein the capacitor component, the inductor component, and the interconnect structure comprise a carbon-containing metallic material.

17. The semiconductor device of claim 13, wherein the shielding assembly comprises:
a plurality of first shielding members extending along a second direction and substantially equally spaced in a third direction, wherein the second direction is different from the first direction and the third direction is perpendicular to the second direction;
a plurality of second shielding members extending along the second direction and substantially equal spaced in the third direction, wherein the plurality of first shielding members are on opposite sides of the signal line along a fourth direction that is perpendicular to the first direction; and
a pair of third shielding members extending along the first direction and on opposite sides of the signal line along the first direction, wherein the third shielding members connect the plurality of first shielding members to the plurality of second shielding members.

18. A method of manufacturing a semiconductor device, comprising:
providing a substrate;
forming a first interconnect layer over the substrate, wherein the first interconnect layer comprising a capacitor component and a first interconnect structure laterally surrounding the capacitor component; and
forming a second interconnect layer over the first interconnect layer, wherein the second interconnect layer comprises an inductor component vertically aligned with the capacitor component and a second interconnect structure laterally surround the inductor component and electrically connected to the first interconnect structure.

19. The method of claim 18, further comprising depositing an insulating layer between the first interconnect layer and the second interconnect layer.

20. The method of claim 19, wherein the second interconnect layer comprises alternating conductive lines and conductive vias, and at least one bottommost conductive line of the inductor component is disposed in the insulating layer.
